(19) United States
(12) Patent Application Publication
(10) Pub. No.: US 2026/0231346 A1
(43) Pub. Date: Aug. 6, 2026

(54) INTEGRATED BRUSH AND BEND RADIUS PROTECTOR

(71) Applicant: viaPhoton, Inc., Naperville, IL (US)

(72) Inventors: Mark James Smrha, Chicago, IL (US); Mark Van den Avont, Arlington Heights, IL (US)

(21) Appl. No.: 19/530,167

(22) Filed: Feb. 4, 2026

Related U.S. Application Data
(60) Provisional application No. 63/753,806, filed on Feb. 4, 2025.

(51) Int. Cl. H05K 5/02

(52) U.S. Cl. CPC H05K 5/0247

(57) ABSTRACT

An apparatus includes a housing and a waterfall. The housing including an aperture formed at an edge of the housing and configured to receive at least one cable. The waterfall positioned around the aperture and configured to rotate to block the edge of the housing.

### CROSS-REFERENCE TO RELATED APPLICATION AND PRIORITY CLAIM

This application claims priority under 35 U.S.C. § 119(e) to U.S. Provisional Patent Application No. 63/753,806 filed on February 4, 2025, which is hereby incorporated by reference in its entirety.

### TECHNICAL FIELD

This disclosure relates generally to cable routing systems and processes. More specifically, this disclosure relates to an integrated brush and bend radius protector.

### BACKGROUND

Data centers and telecommunication facilities depend on the efficient management of fiber optic and other types of cables to maintain functionality and performance. Cable routing systems often incorporate brush glands, which serve as barriers to prevent the ingress of debris into sensitive areas while allowing cables to pass through physical enclosures. While effective at blocking debris, these designs impose significant challenges during cable installation. Traditional systems require one end of the cable to be fed through the opening, necessitating careful routing and manipulation, which becomes especially burdensome for pre-terminated cables or in scenarios requiring frequent modifications to cable layouts.

### SUMMARY

This disclosure provides an integrated brush and bend radius protector.

In a first embodiment, an apparatus can include a housing and a waterfall. The housing can include an aperture formed at an edge of the housing and configured to receive at least one cable. The waterfall can be positioned around the aperture and configured to rotate to block the edge of the housing.

In a second embodiment, a system can include a rack and a component. The component can include a housing and a waterfall. The housing can include an aperture formed at an edge of the housing and configured to receive at least one cable. The waterfall can be positioned around the aperture and configured to rotate to block the edge of the housing.

In one or more of the above embodiments, the apparatus or system can further include a brush gland positioned in the aperture of the housing and configured to seal the aperture when the at least one cable is thread through the aperture.

In one or more of the above embodiments, the brush gland may include a plurality of bristles arranged in a dense, overlapping pattern to provide sufficient coverage across the aperture.

In one or more of the above embodiments, the brush gland may include a backing that interfaces with a mounting surface of the housing and configured to provide structural support for the bristles.

In one or more of the above embodiments, the backing may be flexible or irregular shaped to accommodate curved or irregular surfaces of the aperture of the housing.

In one or more of the above embodiments, the waterfall may include a flange, and the housing further includes a track configured to guide rotational movement of the flange.

In one or more of the above embodiments, a geometry of the track may prevent misalignment of the waterfall with the track.

In one or more of the above embodiments, the track may be further configured to enable the waterfall to toggle between an open position and a closed position.

In one or more of the above embodiments, the track may further include a locking mechanism to hold the waterfall securely in the open position and the closed position.

In one or more of the above embodiments, the waterfall may have a rounded profile to promote a gradual curve of the at least one cable.

Other technical features may be readily apparent to one skilled in the art from the following figures, descriptions, and claims.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example rack in accordance with this disclosure;

FIGS. 2A and 2B illustrate an example housing with an attached brush gland in accordance with this disclosure;

FIGS. 3A and 3B illustrate an example interface between the brush gland and waterfall in accordance with this disclosure;

FIGS. 4A and 4B illustrate an example brush gland in accordance with this disclosure; and

FIGS. 5A and 5B illustrate example brush glands in accordance with this disclosure.

### DETAILED DESCRIPTION

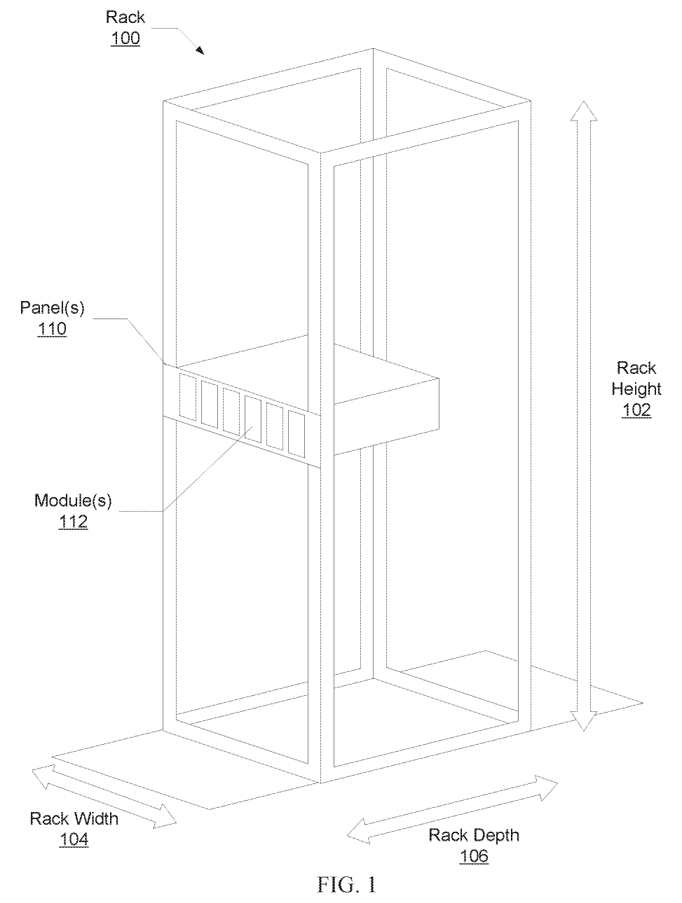

FIGS. 1 through 5B, described below, and the various embodiments used to describe the principles of the present disclosure are by way of illustration only and should not be construed in any way to limit the scope of the disclosure. Those skilled in the art will understand that the principles of the present disclosure may be implemented in any type of suitably arranged device or system.

This disclosure provides a unique brush gland that allows more convenient insertion and removal of the cable. This brush gland allows cables to be inserted into the brush gland while both ends are fixed at any location. The brush gland can also be made with bend radius protection, which is semi-permanently attached to the brush gland and allows the same installation functionality while also adding the benefit of bend radius protection.

FIG. 1 illustrates an example rack in accordance with this disclosure. As shown in FIG. 1, the rack 100 is a piece of telecommunications equipment that provides for the housing and organization of diverse telecommunication devices

The outer dimensions of rack 100, including rack width 104 and rack depth 106, aligns with the widths of most network and server equipment. For example, rack width 104 may measure 19 inches (48.26 cm) or 23 inches (58.42 cm) in width, standard measurements that are adhered to in the telecommunications industry. Other dimensions may be used, e.g., 21 inches, 23 inches, etc. The rack height 102, and rack width 104, and rack depth 106 dimensions ensure that the rack can accommodate equipment with different form factors, such as 1U, 2U, or larger units, where "U" represents a standard rack unit of measure equal to 1.75 inches in height.

The rack 100 may include a series of uniformly spaced vertical mounting slots, located on both the front and rear, to facilitate the arrangement and mounting of various telecommunication devices and components. The slots serve as attachment points for mounting the panel(s) 110. The rack 100 may further be equipped with additional features such as ventilation openings and cable management.

Panel(s) 110 are components that mount within the rack 100 to organize, secure, and provide access to connective hardware. Panel(s) 110 are formed with standardized form factors for compatibility with the mounting slots of the rack 100. For example, panel(s) 110 may include standardized mounting points to align with rack units, a layout that supports the intended cable or connector density, and provisions for labeling and user accessibility.

The panel(s) 110 may be equipped with one or more module(s) 112 to secure the fibers using ports, connector adapters, connectors, etc. Module(s) 112 are prefabricated units or sub-assemblies designed for quick installation into the rack 100. The module(s) 112 may house electronic components, such as switches, routers, or patches. The module(s) 112 may include features for splicing, cable management, and security.

The dimensions of the module(s) 112 conforms to the standard dimensions of a rack (100). For example, the height of module(s) 112 may be 1 RU, or a multiple the standard 1 RU dimension, e.g., 2 RU, 3 RU, etc. The width for each of the module(s) 112 may enable a group of the module(s) 112 to fit within one of the panel(s) 110. For example, the width of each module(s) 112 may be selected such that a number of modules (e.g., 4, 6, 8, 10, 12, etc.) can be accommodated within the rack width 104.

The front end of the module(s) 112 is exposed through the front of one of the panel(s) 110 and through the front of the rack 100. The front end of the module(s) 112 may include interfaces for power and data connectivity. For example, the module(s) 112 may include a group of the connector adapters to accommodate one or more optical connectors, such as LC connectors, SC connectors, ST connectors, etc.

Although FIG. 1 illustrates an example rack, various changes may be made to FIG. 1. For example, the number and placement of various components of the rack 100 can vary as needed or desired.

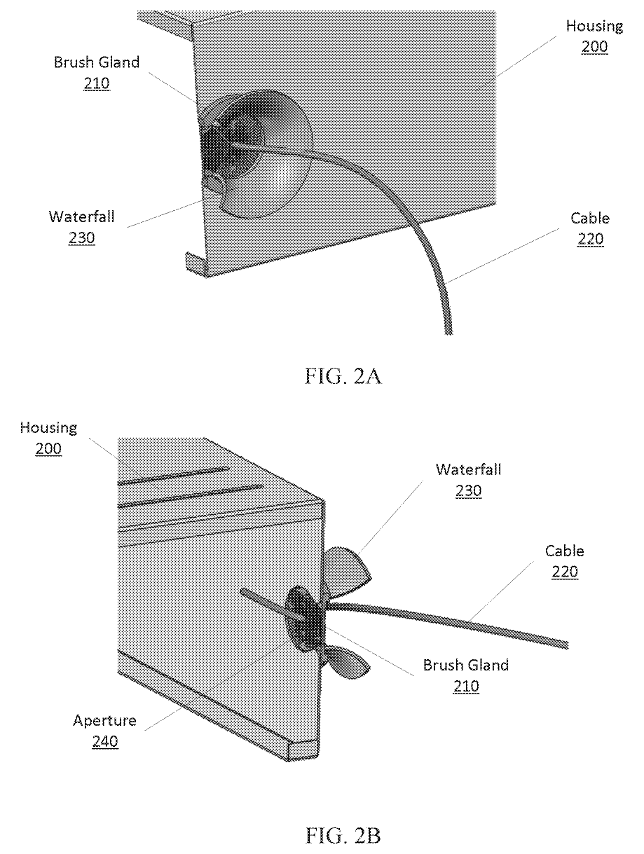

FIGS. 2A and 2B illustrate an example housing 200 with an attached brush gland 210 in accordance with this disclosure. The housing 200 may be an enclosure for one or more components attached to rack 100 of FIG. 1 As shown in FIGS. 2A and 2B, housing 200 is a structural element that forms an enclosure or surface for supporting the cable routing system. The housing 200 may be constructed from rigid materials such as steel, aluminum, or reinforced plastics to ensure structural stability and durability in data center environments. The housing 200 defines an aperture 240 through which cables 220 are routed and interface with other components of the system, such as the brush gland 210 and the waterfall 230. The dimensions and geometry of the housing 200 may vary depending on the application, but the housing 200 includes flat or contoured surfaces to support mounting and integration with adjacent structures.

The housing 200 includes aperture 240. The aperture 240 is an opening in the housing 200 that allows cables 220 to pass through the housing 200 while serving as a point of interface for additional components like the brush gland 210 and the waterfall 230. The aperture 240 can be rectangular, circular, or custom-shaped depending on the system requirements. The material surrounding the aperture 240 is typically machined or molded to precise tolerances to ensure compatibility with mounting mechanisms for the attached components. The size of aperture 240 is selected to accommodate the desired cable types, which may include fiber optic cables, electrical cables, or hybrid cabling systems. In certain embodiments, the aperture 240 is positioned at an edge of the housing 200 in a manner that the aperture is open at an edge of the housing 200.

The brush gland 210 is a debris management component that seals the aperture 240 while allowing for passage of cable 220. The brush gland 210 consists of flexible bristles or filaments, which may be composed of nylon, polypropylene, or other synthetic materials resistant to wear and environmental factors. The brush gland 210 prevents large particles or contaminants from entering the housing 200 while allowing cables to slide through with minimal friction. The backing of the brush gland 210 is designed for easy installation, often including grooves or mounting flanges that secure the component to the housing 200. The shape of the brush gland 210 can be circular or rectangular to match the geometry of the aperture 240.

The brush gland 210 can include an open portion 212. The open portion 212 corresponds to the portion of the aperture 240 at an edge of the housing 200 where the housing does not surround the aperture 240. The brush gland 210 can extend from both side of the housing 200 to complete the coverage of the aperture 240. The arrangement of the brushes of the brush gland 210 allow for a cable to be fed from a side of the housing 200 instead of through the aperture 240 of the housing 200.

The cable 220 is a medium for data or electrical transmission routed through the aperture and brush gland. Cables 220 used in this application may include fiber optic cables for high-speed data transfer or insulated copper cables for electrical connectivity. The cable 220 is designed to maintain flexibility while ensuring structural integrity, with a protective jacket material such as polyethylene or PVC. The cable 220 interacts with other components, such as the brush gland 210 and waterfall 230, to ensure safe routing without physical damage or signal degradation.

The waterfall 230 is a bend radius protection feature that ensures cables 220 are routed without exceeding their maximum bend radius, thereby preventing mechanical stress or damage to the internal conductors or fibers. The waterfall 230 may be manufactured from materials such as ABS plastic or powder-coated aluminum to provide durability and smooth contact surfaces for cables. The waterfall 230 is designed with a rounded profile to promote a gradual curvature of the cable 220 as it passes through the aperture 240 of the housing 200.

The waterfall 230 is shown in an open position 204 to facilitate insertion of one or more cables 220. The open position 204 allows cables 220 to be installed without threading through the brush gland, simplifying installation and maintenance processes.

Although FIGS. 2A and 2B illustrate an example housing 200 with an attached brush gland 210, various changes may be made to FIGS. 2A and 2B. For example, the number and placement of various components of the housing 200 can vary as needed or desired.

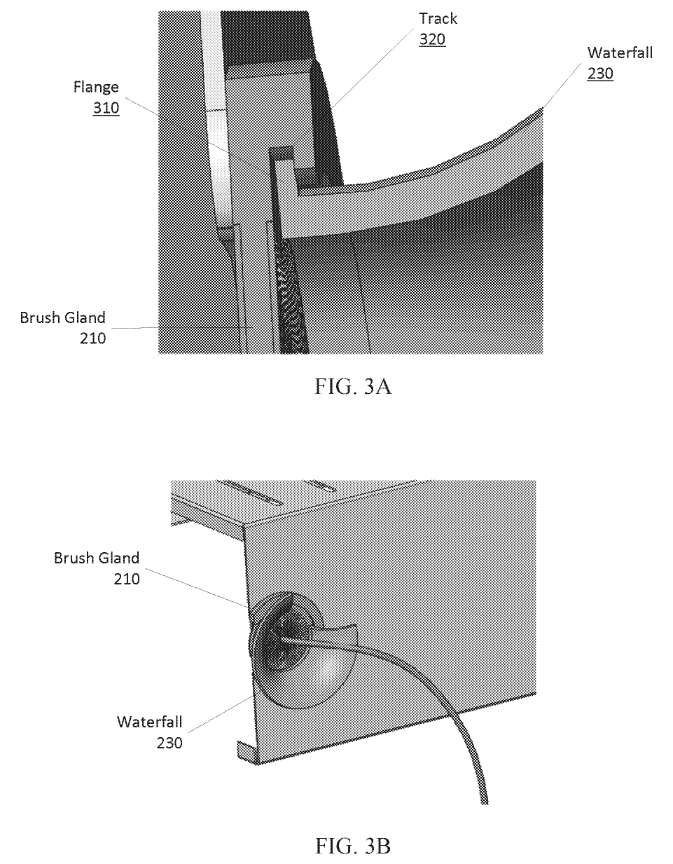

FIGS. 3A and 3B illustrate an example interface 300 between the brush gland 210 and waterfall 230 in accordance with this disclosure. As shown in FIGS. 3A and 3B, flange 310 is an integral part of the waterfall 230 and serves as the rotational interface with the track 320 for the rotation of the waterfall 230 about the aperture 240 of the housing 200. The flange 310 is typically fabricated from durable materials such as ABS plastic, aluminum, or reinforced polymers to provide structural integrity and ensure smooth rotation. The flange 310 includes a central pivot point or similar feature that engages with the track 320, allowing the waterfall 230 to rotate between open position 204 (shown in FIG. 2A) and closed position 304 (shown in FIG. 3B). The outer geometry of the flange 310 is designed to maintain alignment and prevent unintended displacement during operation. The rotational design of flange 310 allows the waterfall 230 to selectively align or misalign its open portion with the brush gland 210 to control cable access.

Track 320 is an integrated feature of the brush gland 210, designed to guide and secure the rotational movement of the flange 310. Typically constructed from low-friction materials such as PTFE or high-density polyethylene, the track 320 includes a groove or slot that accommodates the flange 310 and ensures smooth, controlled rotation. The track 320 defines the rotational path of the flange 310, enabling the waterfall 230 to toggle between open position 204 and the closed position 304. The geometry of the track 320 prevents misalignment and provides a locking mechanism 322 to hold the waterfall 230 securely in the desired position, whether the open position 204 or the closed position 304.

The open portion 232 of the waterfall 230 can be rotationally aligned or misaligned with the open portion 212 of the brush gland 210. In the closed position 304 illustrated in FIG. 3B, the rotational movement of the flange 310 within the track 320 misaligns the open portion 232 of the waterfall 230 with the open portion 212 of the brush gland 210. This misalignment creates a physical barrier that prevents cable egress, ensuring that cables remain securely routed through the system. The physical barrier is the waterfall 230.

Although FIGS. 3A and 3B illustrate an example interface 300 between the brush gland 210 and waterfall 230, various changes may be made to FIGS. 3A and 3B. For example, the number and placement of various components of the interface 300 can vary as needed or desired.

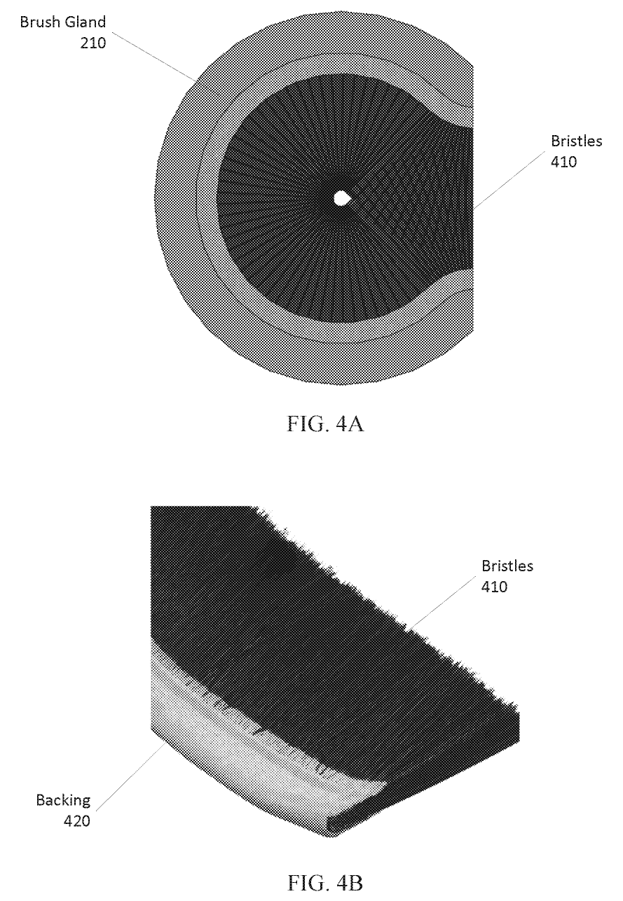

FIGS. 4A and 4B illustrate an example brush gland 210 in accordance with this disclosure. As shown in FIGURESE 4A and 4B, the brush gland 210 can include bristles 410 and a backing 420.

Bristles 410 are the flexible elements of the brush gland 210, configured to create a sealing barrier while permitting the passage of cables 220. These bristles 410 are typically manufactured from wear-resistant materials such as nylon, polyester, or other synthetic fibers to ensure long-term performance. The bristles 410 are arranged in a dense, overlapping pattern to provide sufficient coverage while maintaining flexibility. The length and thickness of the bristles 410 can be adjusted based on the size of the aperture 240 and the cables 220 to be routed. The flexibility of the bristles 410 allows the bristles 410 to bend around cables 220, forming a seal that minimizes air or particulate flow. Bristles 410 are often treated or coated with anti-static or lubricating agents to further enhance performance in specialized environments such as data centers or telecommunication facilities.

Backing 420 is the structural support component that secures the bristles 410 in place and interfaces with the mounting surface. Typically constructed from durable materials such as steel, aluminum, or high-strength plastics, the backing ensures the structural integrity of the brush gland. The backing 420 may feature grooves, flanges, or other attachment mechanisms that enable secure to the body of the brush gland 210. The backing 420 may also include a flexible or articulated section to accommodate curved or irregular surfaces, expanding the versatility of the brush gland. Depending on the application, the backing 420 may be coated with protective finishes such as powder coating or anodizing to resist corrosion and wear.

Although FIGS. 4A and 4B illustrate an example brush gland 210, various changes may be made to FIGS. 4A and 4B. For example, the number and placement of various components of the brush gland 210 can vary as needed or desired.

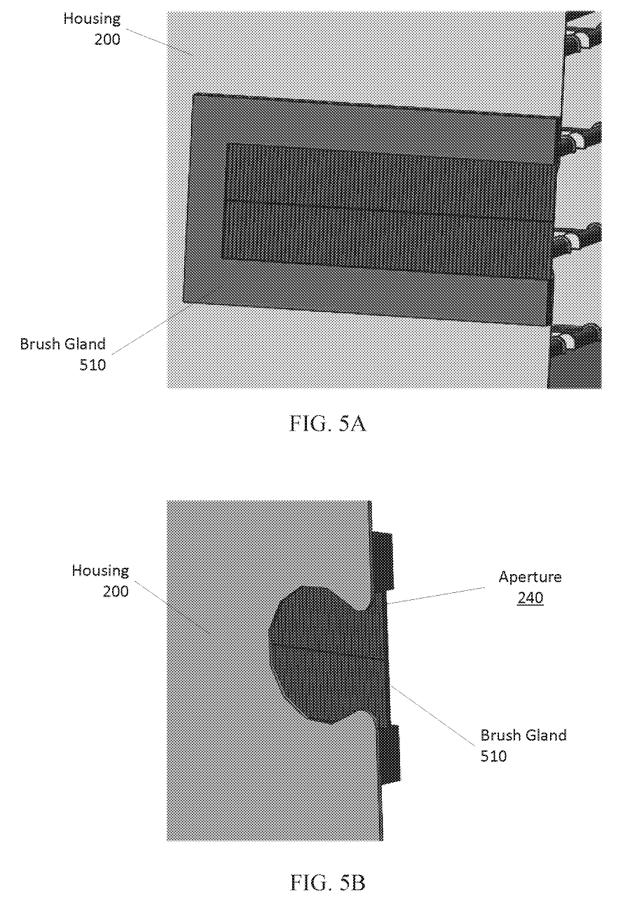

FIGS. 5A and 5B illustrate example brush gland 510 in accordance with this disclosure. As shown in FIG. 5A, the brush gland 510 can have a rectangular shape. The rectangular shape of the brush gland 510 provides for a more orderly, linear arrangement of the bristles 410 than the circular shape of brush gland 520.

Although FIGS. 5A and 5B illustrate an example brush gland 210, various changes may be made to FIGS. 5A and 5B. For example, the number and placement of various components of the brush gland 210 can vary as needed or desired.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. An apparatus comprising:
a housing comprising an aperture formed at an edge of the housing and configured to receive at least one cable; and
a waterfall positioned around the aperture and configured to rotate to block the edge of the housing.

2. The apparatus of claim 1, further comprising:
a brush gland positioned in the aperture of the housing and configured to seal the aperture when the at least one cable is thread through the aperture.

3. The apparatus of claim 2, wherein the brush gland includes a plurality of bristles arranged in a dense, overlapping pattern to provide sufficient coverage across the aperture.

4. The apparatus of claim 3, wherein the brush gland includes a backing that interfaces with a mounting surface of the housing and configured to provide structural support for the bristles.

5. The apparatus of claim 4, wherein the backing is flexible or irregular shaped to accommodate curved or irregular surfaces of the aperture of the housing.

6. The apparatus of claim 1, wherein:
the waterfall includes a flange; and
the housing further includes a track configured to guide rotational movement of the flange.

7. The apparatus of claim 6, wherein a geometry of the track prevents misalignment of the waterfall with the track.

8. The apparatus of claim 6, wherein the track is further configured to enable the waterfall to toggle between an open position and a closed position.

9. The apparatus of claim 8, wherein the track further includes a locking mechanism to hold the waterfall securely in the open position and the closed position.

10. The apparatus of claim 1, wherein the waterfall has a rounded profile to promote a gradual curve of the at least one cable.

11. A system comprising:
a rack;
a component inserted into the rack, the component comprising:
a housing comprising an aperture formed at an edge of the housing and configured to receive at least one cable; and
a waterfall positioned around the aperture and configured to rotate to block the edge of the housing.

12. The system of claim 11, wherein the component further comprises:
a brush gland positioned in the aperture of the housing and configured to seal the aperture when the at least one cable is thread through the aperture.

13. The system of claim 12, wherein the brush gland includes a plurality of bristles arranged in a dense, overlapping pattern to provide sufficient coverage across the aperture.

14. The system of claim 13, wherein the brush gland includes a backing that interfaces with a mounting surface of the housing and configured to provide structural support for the bristles.

15. The system of claim 14, wherein the backing is flexible or irregular shaped to accommodate curved or irregular surfaces of the aperture of the housing.

16. The system of claim 11, wherein:
the waterfall includes a flange; and
the housing further includes a track configured to guide rotational movement of the flange.

17. The system of claim 16, wherein a geometry of the track prevents misalignment of the waterfall with the track.

18. The system of claim 16, wherein the track is further configured to enable the waterfall to toggle between an open position and a closed position.

19. The system of claim 18, wherein the track further includes a locking mechanism to hold the waterfall securely in the open position and the closed position.

20. The system of claim 11, wherein the waterfall has a rounded profile to promote a gradual curve of the at least one cable.
